(19) United States
(12) Patent Application Publication
(10) Pub. No.: US 2001/0013653 A1
(43) Pub. Date: Aug. 16, 2001

(54) ARRAY OF ELECTRODES RELIABLE, DURABLE AND ECONOMICAL AND PROCESS FOR FABRICATION THEREOF

(76) Inventor: KAZUTAKA SHOJI, TOKYO (JP)

Correspondence Address: NORMAN P SOLOWAY, HAYES SOLOWAY HENNESSEY, GROSSMAN & HAGE PC, 175 CANAL STREET, MANCHESTER, NH, 03101

(21) Appl. No.: 09/370,326

(22) Filed: Aug. 9, 1999

(30) Foreign Application Priority Data
Aug. 17, 1998 (JP) 10-230944

(51) Int. Cl. H01L 23/48; H01L 23/52; H01L 29/40

(52) U.S. Cl. 257/738

(57) ABSTRACT

An array of solder balls is directly covered with a reinforcing resin layer after fixing the solder balls to a conductive pattern by means of conductive paste or during reflow thereof concurrently with the thermosetting step for the reinforcing resin layer so that the manufacturer eliminates a solder resist from between the conductive pattern and the reinforcing resin layer.

### FIELD OF THE INVENTION

This invention relates to an array of electrode and, more particularly, to a structure of an electrode array on an interposer between a semiconductor chip and a package and a process for fabrication thereof.

### DESCRIPTION OF THE RELATED ART

An interposer connects a semiconductor chip to a package, and has electrodes opposed to a surface of the semiconductor chip where electrodes are formed. The connecting technology is used in the ball grid array and the chip size package. The ball grid array and the chip size package are abbreviated as “BGA” and “CSP”, respectively.

The ball grid array consists of conductive balls arranged in matrix, and serves as an interface between a semiconductor chip and a conductive pattern on a package. The chip size package is a kind of the ball grid array package, and is smaller than the standard ball grid array package.

FIGS. 1A to 1L illustrate a prior art process for forming a ball grid array on a polyimide layer. The process starts with preparation of a pad 1. The pad 1 consists of an insulating organic film 1a such as polyimide and a conductive layer 1b of copper as shown in FIG. 1A. The insulating organic film 1a ranges from 20 microns to 50 microns thick, and the conductive pattern 1b is 10 microns to 20 microns thick.

Subsequently, the upper surface of the pad 1 is covered with a photoresist layer 2 as shown in FIG. 1B. The photoresist layer 2 is formed through a pre-baking after spreading photoresist solution. Otherwise, a photosensitive dry film is laminated on the pad 1. The photoresist layer 2 is the negative type, and a portion exposed to light is left on the pad 2.

Subsequently, a photomask 3 is brought into physical contact with the photoresist layer 2, and the photoresist layer 2 is exposed through the photomask to light indicated by arrows in FIG. 1C. A pattern is transferred from the photomask 3 to the photoresist layer 2 through the contact printing technique, and a latent image is formed in the photoresist layer 2.

Subsequently, the photomask 3 is removed, and the latent image is developed. The photoresist exposed to the light is cured. However, the photoresist covered with the photomask is still soluble in developing solution. For this reason, the photoresist layer 2 is partially removed, and the photoresist layer 2 is patterned into the photoresist etching mask as shown in FIG. 1D.

Using the photoresist etching mask 2, the conductive layer 1b is selectively etched away, and is formed into the inverse pattern of the photoresist etching mask. The etchant contains FeCl₃, by way of example. Thus, conductive lands 4a and a wiring pattern 4b are formed on the polyimide film 1a as shown in FIG. 1E.

Subsequently, solder resist 5 is spread over the entire surface of the resultant structure, and is removed from the upper surfaces of the conductive lands 4a as shown in FIG. 1F. The solder resist is of synthetic resin in the polyimide system, in the epoxy system or in the phenol system.

Thereafter, solder balls 6 are formed on the conductive lands 4a, respectively. The solder balls 6 are formed of a kind of eutectic solder, and are conductive. The solder balls 6 have been prepared before the mounting, and flux has been spread over the conductive lands 4a. The solder balls 6 are absorbed with a multi-nozzle head (not shown), and are aligned with the conductive lands 4a, respectively. The flux adheres the solder balls 6 to the conductive lands 4a, respectively. The resultant structure passes through a re-flow furnace (not shown), and the solder balls 6 are bonded to the conductive lands 4a in nitrogen atmosphere at 200 to 250 degrees in centigrade as shown in FIG. 1G. The residual flux is removed from the resultant structure.

Subsequently, a pattern transfer sheet is prepared. The pattern transfer sheet has a rubber plate 7, and the rubber plate 7 is covered with repellent agent 7a. The repellant agent is of fluorine contained polymer, fluorine contained synthetic fluid, paraffin resin or paraffin oil. The pattern transfer sheet is downwardly moved, and the repellent agent 7a is pressed against the solder balls 6 as shown in FIG. 1H. The rubber plate 7 is resiliently deformed, and the repellent agent 7a is brought into contact with fairly wide area. The pattern transfer sheet is upwardly moved, and the repellent agent 7a is left on the solder balls 6 as shown in FIG. 1I.

In this instance, the repellent agent 7a is transferred onto the solder balls 6 through the pattern transfer method. However, the repellent agent may be printed on the solder balls 6, or the solder balls 6 may be dipped into liquid repellent agent.

Subsequently, a dispenser 8a supplies drops of liquid reinforcing resin onto gaps between the solder balls 6 as shown in FIG. 1J. The liquid reinforcing resin is spread over the solder resist layer 5, and covers the exposed surfaces of the solder balls 6. The reinforcing resin is solidified, and most of the exposed surfaces of the solder balls 6 are covered with the reinforcing resin layer 8 like a meniscus as shown in FIG. 1K.

Finally, the repellent agent 7a is removed from the solder balls 6 as shown in FIG. 1L. The repellent agent 7a is dissolved in solvent in this instance. The repellent agent 7a may be mechanically removed by using a lapping sheet. The solder balls 6 serve as electrodes projecting over the polyimide layer 1a. The flux enhances the wettability of the solder, and the solder resist 5 prevents the wiring pattern 4b from the solder. The reinforcing resin layer 8 fixes the solder balls 6 on the conductive lands 4a.

Japanese Patent Publication of Unexamined Application No. 10-98045 discloses a process like the prior art process described hereinbefore. The prior art process disclosed in the Japanese Patent Publication of Unexamined Application improves the resistance against thermal stress so as to prevent the resultant structure from cracks. After the packaging, the electrodes are easily separated from a package.

In the prior art process, a CSP tape or a TAB (Tape Automated Bonding) tape is available for the ball grid array. The CSP tape and the TAB tape have been coated with the solder resist. The wiring pattern on the tape forms an electric circuit together with the integrated circuit in the semiconductor chip to be mounted thereon.

The solder resist layer 5 prevents the wiring pattern 4b from short-circuit, and the reinforcing resin layer 8 fixes the solder balls 6 to the conductive lands 4a. Thus, the prior art ball grid array is reliable and durable. However, a problem is encountered in the prior art ball grid array in the production cost. When using the CSP tape or the TAB tape already covered with the solder resist layer 5, the manufacturer suffers from a high production cost due to the high price of those tapes.

### SUMMARY OF THE INVENTION

It is therefore an important object of the present invention to provide an array of electrodes, which is reliable, durable and economical.

It is also an important object of the present invention to provide a process, through which the array of electrodes is fabricated at low cost.

In accordance with one aspect of the present invention, there is provided an array of electrodes fabricated on an insulating substrate having a conductive pattern on a major surface thereof comprising plural electrodes fixed to the conductive pattern and an insulating resin layer directly covering a remaining portion of the major surface of the insulating substrate and the plural electrodes except surfaces of the plural electrodes so as to anchor the plural electrodes to the insulating substrate.

In accordance with another aspect of the present invention, there is provided a process for fabricating an array of electrodes on an insulating substrate comprising the steps of a) preparing electrodes and an insulating substrate including a conductive pattern formed on a major surface thereof and having conductive lands where the electrodes are to be fixed, b) applying conductive paste on the electrodes or the conductive lands, c) fixing the electrodes to the conductive lands by means of the conductive paste and d) covering the insulating substrate and predetermined surfaces of the electrodes with an insulating resin layer so as to anchor the electrodes to the insulating substrate.

In accordance with yet another aspect of the present invention, there is provided a process for fabricating an array of electrodes on an insulating substrate comprising the steps of a) preparing electrodes and an insulating substrate including a conductive pattern formed on a major surface thereof and having conductive lands where the electrodes are to be fixed, b) making the electrodes on the conductive lands dipped in thermosetting liquid resin spread over the insulating substrate and c) heating the resultant structure of the step b) so as to fix the electrodes to the conductive lands and solidify the thermosetting liquid resin for anchoring the electrodes to the insulating substrate.

### BRIEF DESCRIPTION OF THE DRAWINGS

The features and advantages of the array of electrodes and the process will be more clearly understood from the following description taken in conjunction with the accompanying drawings in which:

FIGS. 1A to 1L are schematic views showing the prior art process;

FIG. 2 is a cross sectional view showing the structure of an array of electrodes on an interposer according to the present invention;

FIGS. 3A to 3J are cross sectional views showing a process for fabricating the array of electrodes on the interposer according to the present invention;

FIG. 4 is a cross sectional view showing a semiconductor device embodying the present invention;

FIGS. 5A and 5B are cross sectional views showing essential steps in a process for fabricating another array of electrodes according to the present invention;

FIGS. 6A to 6C are cross sectional views showing essential steps in a process for fabricating yet another array of electrodes according to the present invention;

FIGS. 7A to 7C are cross sectional views showing essential steps in a process for fabricating still another array of electrodes according to the present invention;

FIGS. 8A to 8D are cross sectional views showing essential steps in a process for fabricating still another array of electrodes according to the present invention; and

FIG. 9 is a plane view showing solder balls inserted into holes formed in a reinforcing resin sheet during the process shown in FIGS. 8A to 8D.

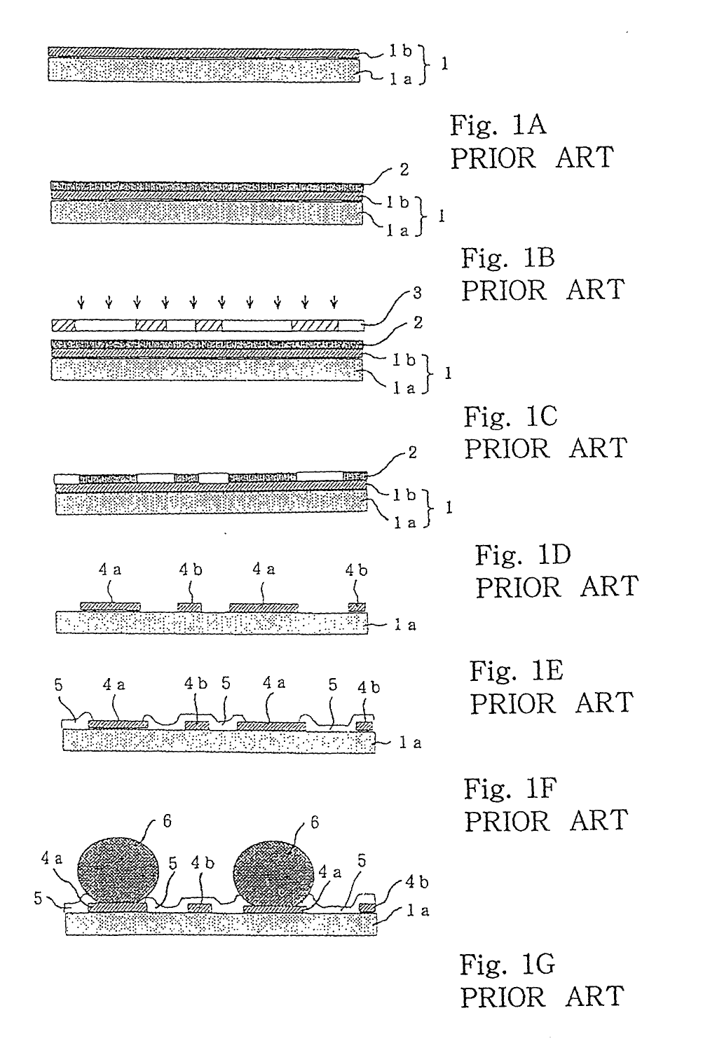

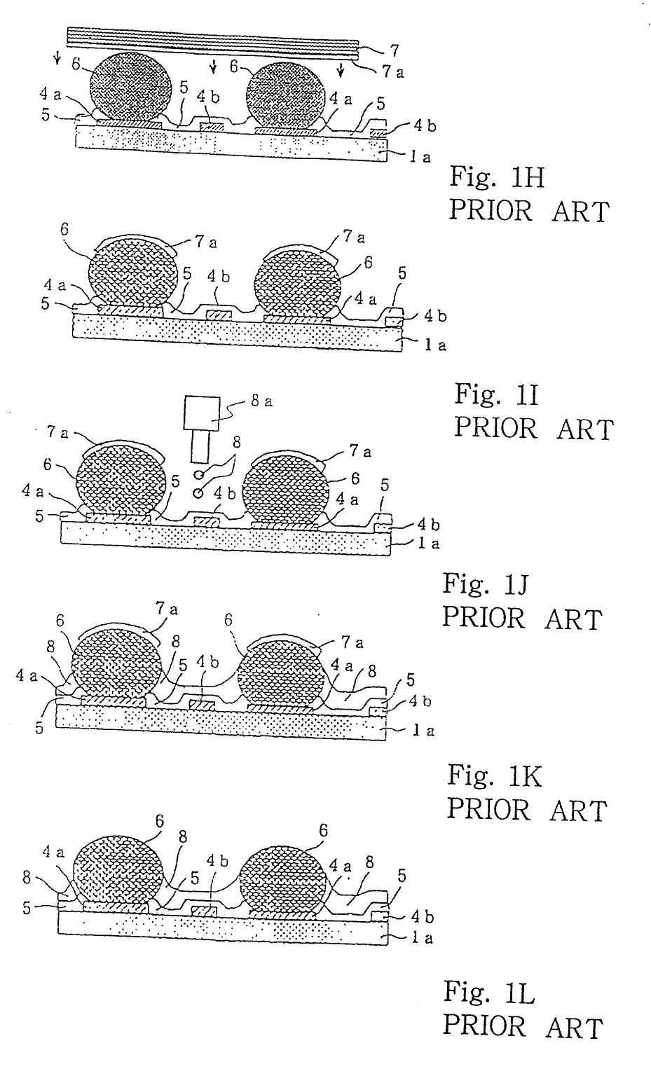

### DESCRIPTION OF THE PREFERRED EMBODIMENTS

First Embodiment

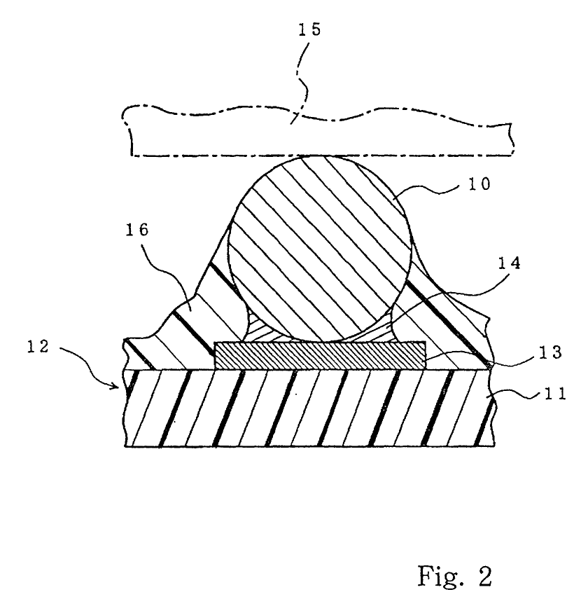

FIG. 2 illustrates an array of electrodes embodying the present invention. A solder ball 10 forms a part of the array, and serves as one of the electrodes. The other solder balls (not shown in FIG. 2) are similar to the solder ball 10, and description is focused on the solder ball 10, only. On an insulating organic film 11 of an interposer 12 is patterned a conductive land 13 to which the solder ball 10 is bonded by means of a piece 14 of conductive paste. Though not shown in FIG. 2, a conductive pattern is further formed on the insulating organic film 11, and the conductive land 13 is integral with the conductive pattern. A part of the conductive pattern connected to the conductive land 13 is electrically isolated from the other part of the conductive pattern, and, accordingly, the solder ball 10 is electrically isolated from the other solder balls. Another solder ball may be electrically connected to yet another solder ball.

The solder ball 10 is formed of eutectic solder, and serves as a bump. Other conductive materials are available for the bump. The bump may be implemented by a high-temperature solder ball, a gold ball or a copper ball. The insulating organic layer 11 is, by way of example, formed from a polyimide film, and the conductive land 13 is formed of copper. The piece 14 of conductive paste is formed of silver paste, gold paste or solder paste. The solder paste contains solder powder dispersed in flux. When the solder paste is selected, the flux is to be removed from the array of electrodes. However, there is a kind of paste, which allows the manufacturer to bond the solder ball 10 to the conductive land 13 without the cleaning.

The solder ball 10 is to be bonded to a printed circuit board 16. For this reason, the solder ball 10 is covered with a reinforcing resin layer 16 except for the upper portion to be bonded to the printed circuit board 15. The exposed upper surface of the insulating organic film 11, the conductive land 13, a conductive pattern (not shown) on the insulating organic film 11 and the piece 14 of conductive paste are perfectly covered with the reinforcing resin layer 16. The reinforcing resin layer 16 anchors the solder ball 10 to the insulating organic film 11, and does not allow the solder ball 10 to move on the conductive land 13. Although the piece 14 of conductive paste bonds the solder ball 10 to the conductive land 13, the reinforcing resin layer 16 enhances the stability of the solder ball 10 on the conductive land 13. The reinforcing resin layer 16 is insulating, and prevents the conductive pattern (not shown) from short-circuit. Thus, the reinforcing resin layer 16 not only enhances the stability of the solder ball 10 but also prevents the conductive patter from short-circuit.

Various kinds of synthetic resin are available for the reinforcing resin layer 16. These kinds of synthetic resin may belong to the polyimide system, the epoxy system, the phenol system, the acrylic system and the silicone system. When the manufacturer selects the synthetic resin, the material of the insulating organic film is taken into account. In this instance, the insulating organic film 11 is formed of polyimide resin, it is appropriate to use the synthetic resin in the polyimide system, the epoxy system, the phenol system or the silicone system. The bonding strength is largest between the insulating organic film 11 of polyimide resin and the synthetic resin in the polyimide system, and is decreased toward the synthetic resin in the silicone system. However, if the insulating organic film 11 is formed of epoxy resin or phenol resin, the synthetic resin is selected from the epoxy system, the phenol system, the acrylic system or the polyimide system. The bonding strength is largest between the insulating organic film of the epoxy resin/phenol resin and the synthetic resin in the epoxy system, and is decreased toward the synthetic resin in the polyimide system.

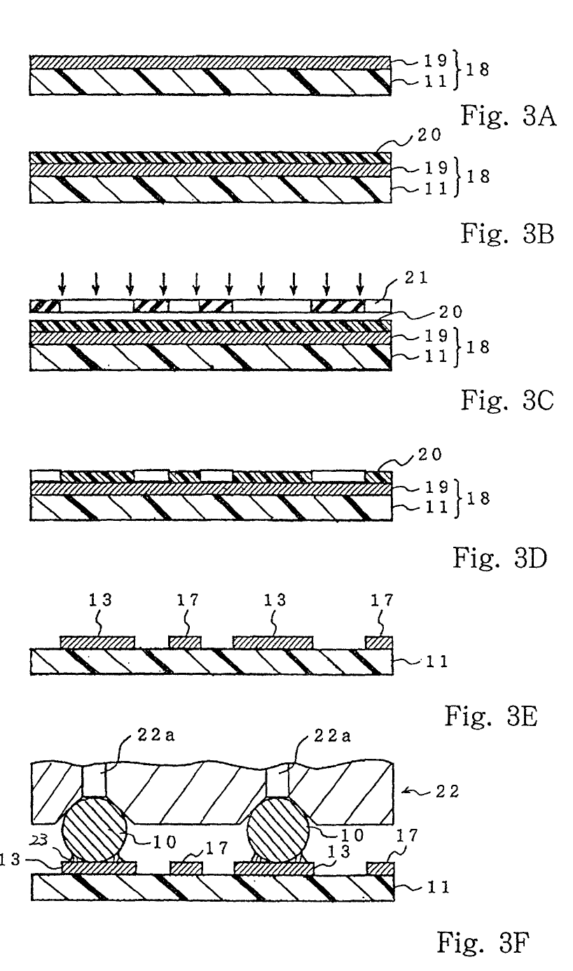

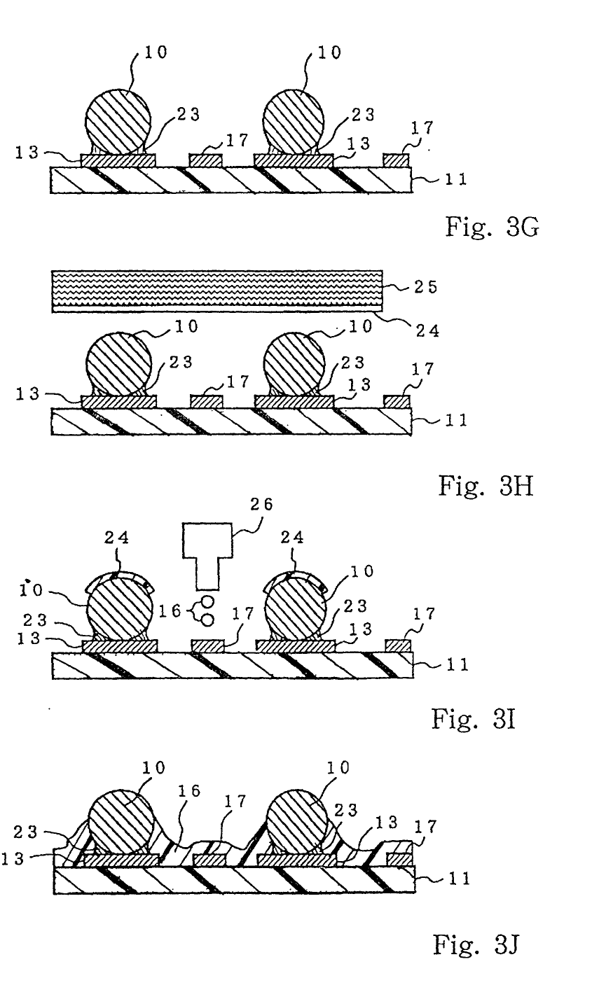

Description is hereinbelow made on a process for fabricating the array of electrodes on the interposer 12 with reference to FIGS. 3A to 3J. The process starts with preparation of a pad 18. The pad 18 has the insulating organic film 11 of polyimide and a copper layer 19 laminated on the insulating organic film 11 as shown in FIG. 3A. In this instance, the insulating organic film 11 is 20 microns to 50 microns thick, and the copper layer 19 is 10 microns to 20 microns thick.

Subsequently, the pad 18 is covered with a photo-resist layer 20 as shown in FIG. 3B. Photo-resist is spread over the copper layer 18, and, thereafter, the photo-resist is pre-baked. Otherwise, a photo-sensitive dry film is bonded onto the copper layer 19. In this instance, the photo-resist layer 20 is of he negative type.

A photomask 21 is provided over the photo-resist layer 20, and the photoresist layer 20 is radiated with light through the photomask 21 as shown in FIG. 3C. The light is indicated by arrows. The photo-resist exposed to the light is polymerized, and is cured. However, the photo-resist under the photomask 21 remains soluble. As a result, the mask pattern is transferred to the photo-resist layer 20, and a latent image is formed therein. The photo-resist layer 20 is selectively dissolved in developing solution as shown in FIG. 3D, and the latent image is developed. The remaining photo-resist layer 20 serves as an etching mask.

Subsequently, the copper layer 19 is selectively etched. The photo-resist etching mask exposes parts of the copper layer 19 to etchant, and the etchant removes the exposed parts of the copper layer 19. In this instance, the etchant contains FeCl₃. As a result, the conductive lands 13 and a conductive pattern 17 are left on the insulating organic film 11 as shown in FIG. 3E. The conductive pattern 17 is integral with the conductive lands 13.

Subsequently, the silver paste 23 is printed on the conductive lands 13. A vacuum clamper 22 absorbs the solder balls 10. Vacuum passages 22a are formed in the vacuum clamper 22, and are open to the lower surface of the vacuum clamper 22. The vacuum clamper 22 carries the solder balls 10 to the conductive lands 13, and aligns the solder balls 10 with the conductive lands 13, respectively, as shown in FIG. 3F. The silver paste 23 is thermally cured so as to bond the solder balls 10 to the conductive lands 13, respectively, as shown in FIG. 3G. Thus, the solder balls 10 are not reflowed, and, accordingly, any flux is required for the solder balls 10. The silver paste 23 is conductive, and the solder balls 10 are electrically connected to the conductive lands 13, respectively.

Subsequently, a pattern transfer sheet is prepared, and is moved over the solder balls 10 as shown in FIG. 3H. Repellent agent 24 is spread over the lower surface of a rubber plate 25. The repellent agent 24 is of fluorine contained polymer, fluorine contained synthetic fluid, paraffin resin, paraffin oil, silicone resin or silicone oil. The solder balls 10 may be coated with the repellent agent through a printing or dipping.

The repellent agent 24 is pressed against the solder balls 10. The rubber plate 25 is resiliently deformed along the surfaces of the solder balls 10, and brings the repellent agent 24 to the upper portions of the solder balls 10. Thus, the upper portions of the solder balls 10 are coated with repellent agent layers 24. The heating temperature is 120 degrees to 150 degrees in centigrade.

Subsequently, low-viscous liquid resin 16 is dropped from a dispenser 26 to between the solder balls 10 as shown in FIG. 3I. The repellent agent 24 prevents the upper portions of the solder balls 10 from the liquid resin, and the liquid resin is spread over the remaining surface of the resultant structure. The exposed surface of the insulating organic film 11, the conductive pattern 17 and the exposed surfaces of the solder balls 10 are covered with the reinforcing resin layer 16 like a meniscus. The reinforcing resin layer enhances the stability of the solder balls 10 on the conductive lands 13.

The liquid resin layer 16 is solidified, and, thereafter, the repellent agent 24 is removed from the solder balls 10. When the reinforcing resin belongs to the epoxy system or the phenol system, the liquid resin 16 is thermally cured at 100 degrees to 150 degrees in centigrade. If the reinforcing resin belongs to the polyimide system, the liquid resin 16 is thermally cured at 100 degrees to 250 degrees in centigrade. The repellent agent 24 is chemically or mechanically removed. When the repellent agent 24 is chemically removed, appropriate solvent is used. A lapping sheet may be used in the mechanical removal. Thus, the upper portions of the solder balls 10 are exposed, again. The resultant structure is shown in FIG. 3J.

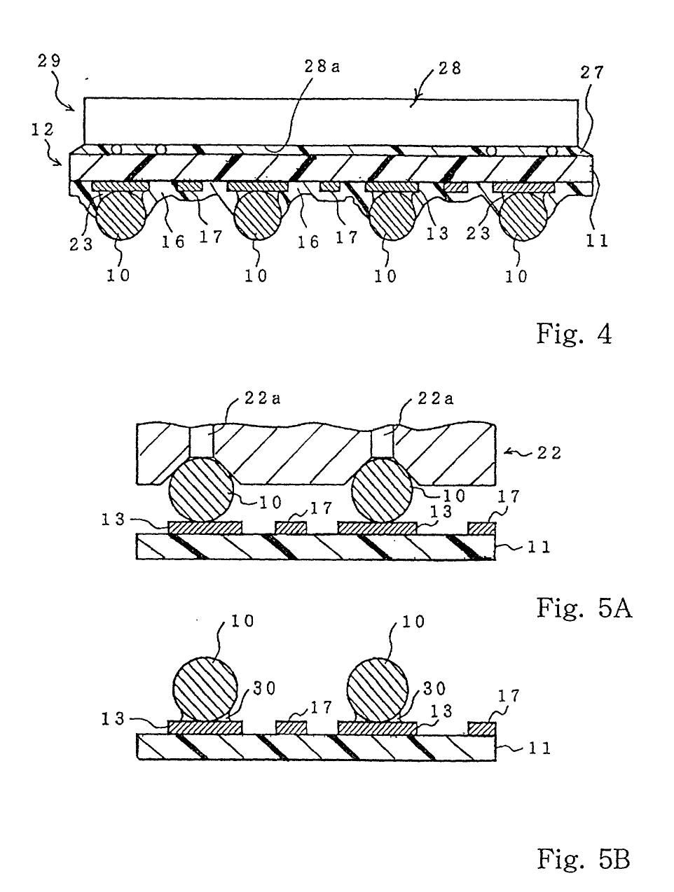

The array of electrodes on the interposer 12 is assembled with a semiconductor chip 28 as shown in FIG. 4. Circuits components are integrated in the semiconductor chip 28, and form an integrated circuit. The array of electrodes on the interposer 12 and the semiconductor chip 28 as a whole constitute a semiconductor device. The semiconductor chip 28 has a reverse surface 28a, and electrodes are formed on the reverse surface 28a. Small bubbles represent the electrodes. Though not shown in FIG. 4, the conductive pattern 17 passes through via holes formed in the insulating organic film 11, and extends on the reverse surface. The interposer 12 is fixed to the semiconductor chip by means of adhesive compound 27, and the electrodes of the semiconductor chip 28 are connected to the conductive pattern on the reverse surface of the insulating organic film 11. Thus, the integrated circuit is electrically connected through the electrodes and the conductive pattern 17 to the solder balls 10. The semiconductor device 29 is, by way of example, mounted on a circuit board (not shown), and forms a part of an electronic system.

As will be understood from the foregoing description, the reinforcing resin layer 16 enhances the stability of the solder balls 10 on the conductive lands 23, and offers the electric insulation to the conductive pattern 17. Any solder resist is not required for the array of electrodes on the interposer 12, nor any CPS/TAB tape already covered with the solder resist. For this reason, the manufacturer fabricates the array of electrodes on the interposer 12 at a low cost.

Moreover, the solder balls 10 are fixed to the conductive lands 13 by means of the conductive paste 23. The solder balls 10 are never reflowed, nor any flux is required. This means that the process does not contain the cleaning step for residual flux. Thus, the process according to the present invention is simpler than the prior art process, and the simple process makes the manufacturer reduce the production cost of the semiconductor device.

Second Embodiment

Another array of electrodes embodying the present invention is similar to the first embodiment except the connection between the solder balls 10 and the conductive lands 13. For this reason, description is focused on different steps of a process for fabricating the array of electrodes on an interposer. In the following description and FIGS. 5A and 5B, components of the second embodiment are labeled with the same references designating corresponding components of the first embodiment without detailed description.

In the process for the second embodiment, solder paste is used for connecting the solder balls 10 to the conductive lands 13. Upon completion of the pattering step for the conductive lands 13 and the conductive pattern 17, the solder balls 10 are clamped by the vacuum clamper 22, and the solder paste is adhered to lower portions of solder balls 10. The vacuum clamper 22 carries the solder balls onto the conductive lands 13, and puts the solder balls 10 on the conductive lands 13 as shown in FIG. 5A. The solder paste is viscous, and keeps the solder balls 10 on the conductive lands 13. The solder paste may be printed on the conductive lands 13 before the solder balls 10 are brought into contact with the conductive lands 13.

Subsequently, the resultant structure passes through a reflow furnace (not shown). Nitrogen atmosphere at 200 degrees to 250 degrees in centigrade is created in the reflow furnace, and the solder power in the paste is melted. The melted solder is cooled, and the solder balls 10 are fixed to the conductive lands 13 by means of meniscus-like solder pieces 30, respectively, (see FIG. 5B). The remaining flux is removed from the resultant structure. If the solder paste is of the type free from the cleaning, the process sequence is simple. After the step of fixing the solder balls 10 to the conductive lands 13, the process sequence returns to the step shown in FIG. 3H.

It is appropriate to use the solder powder lower in melting point than the solder balls 10. A belt furnace is available for the reflow, and the solder powder is melted around 230 degrees in centigrade. The reflow may be carried out in any kind of non-oxidizing atmosphere.

The solder paste is desirable rather than the eutectic solder. The solder resist is indispensable to the eutectic solder, because the eutectic solder flows out of the conductive lands 13. When the solder paste is melted, the melted solder is adhered between the conductive lands 13 and the solder balls 10 like a meniscus, and does not flow out of the conductive lands 13. Thus, the solder paste allows the manufacturer to eliminate the solder resist from the array of electrodes on the interposer 12. Any CSP/TAB tape coated with the solder resist is not required for the array of electrodes according to the present invention. As a result, only the reinforcing resin layer 16 is required for the array of electrodes fabricated on the interposer 12, and the manufacturer can fabricate the array of electrodes at a low cost.

Third Embodiment

Yet another array of electrodes embodying the present invention is similar in structure to the first and second embodiments. However, a process for the third embodiment is different from those for the first and second embodiments. In the processes for the first embodiment and the second embodiment, the solder balls 10 are firstly fixed onto the conductive lands 13, and, thereafter, the resultant structure is partially covered with the reinforcing resin layer 16 through the thermal curing. The process for the third embodiment concurrently carries out the fixing step and the thermal curing.

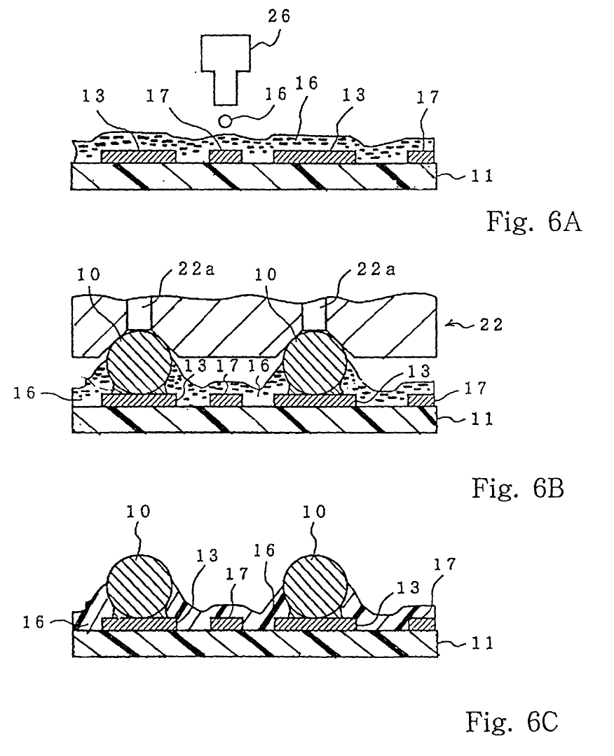

The process sequence is similar to the process for the first embodiment until the step shown in FIG. 3E. FIGS. 6A to 6C illustrate essential steps after the step shown in FIG. 3E.

The dispenser 26 supplies drops of liquid resin 16 onto the insulating organic film 11, and the liquid resin is spread over the entire surface. The exposed area of the insulating organic film 11, the conductive lands 13 and the conductive pattern 17 are covered with the liquid resin layer 16 as shown in FIG. 6A. The liquid resin may be printed on the insulating organic film 11. Flux may be spread on the conductive lands 13 before spreading the liquid resin.

Subsequently, the solder balls 10 are clamped with the vacuum clamper 22, and are pressed against the conductive lands 13. The solder balls 10 push away the liquid resin 16, and are brought into contact with the conductive lands 13. The solder balls 10 get the lower portions wet, and make the liquid resin layer 16 meniscus. The solder balls 10 are continuously pressed against the conductive lands 13, and supersonic vibrations are applied to the solder balls 10. The friction between the solder balls 10 and the conductive lands 13 makes the solder balls 10 bonded to the conductive lands 13, respectively as shown in FIG. 6B. For this reason, it is desirable to use low-viscous liquid resin.

The vacuum clamper 22 releases the solder balls 10, and the liquid resin is solidified. In this instance, the resultant structure is placed into high-temperature nitrogen atmosphere, and the liquid resin is baked and solidified. As a result, the power portions of the solder balls 10, the exposed areas of the conductive lands 13, the conductive pattern 17 and the exposed area of the insulating organic film 11 are covered with the reinforcing resin layer 16 as shown in FIG. 6C. When the liquid resin belongs to the polyimide system, the nitrogen atmosphere is heated to 150 degrees to 250 degrees in centigrade.

While the high-temperature nitrogen atmosphere is baking the liquid resin, the solder balls 10 are strongly fixed to the conductive lands 13. The reinforcing resin layer 16 enhances the stability of the solder balls 10 on the conductive lands 13.

If the solder balls 10 are, by way of example, 0.8 millimeter in diameter, the liquid resin 16 tends to reach upper portions of the solder balls 10, and the reinforcing resin may be chemically or mechanically removed from the upper portions of the solder balls 10 by using solvent or a lapping sheet.

As will be understood from the foregoing description, the solder balls 10 are temporarily fixed to the conductive lands 13 by using the supersonic vibrations after covering the entire surface with the liquid resin 16, and are strongly fixed to the conductive lands 13 during the solidification of the liquid resin 16. The reinforcing resin layer 16 prevents the melted solder to flow out of the conductive lands 13. For this reason, the array of electrodes fabricated on the interposer 12 does not require any solder resist layer, and is fabricated at low cost by virtue of the elimination of solder resist layer.

Fourth Embodiment

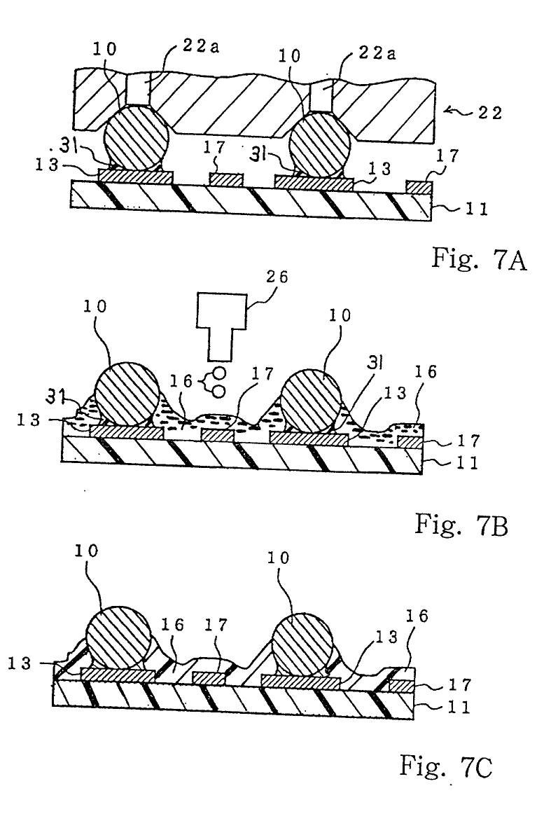

Still another array of electrodes embodying the present invention is similarly fabricated on the interposer 12. However, the solder balls 10 are placed on the conductive lands 13 before covering the conductive pattern with the liquid resin. A fabrication process for the fourth embodiment is similar to the process for the first embodiment until the step shown in FIG. 3E, and the remaining steps are described with reference to FIGS. 7A to 7C.

The solder balls 10 are clamped with the vacuum clamper 22, and lower portions of the solder balls 10 are coated with flux 31. The flux is of the type free from the cleaning, and, accordingly, does not deteriorate the array of electrodes fabricated on the interposer 12. The solder balls 10 are aligned with the conductive lands 13, and are put on the conductive lands 13, respectively. The flux 31 is dried, and the solder balls 10 are temporarily fixed to the conductive lands 13 as shown in FIG. 7A. The flux 31 may be printed on the conductive lands 13 before the step shown in FIG. 7A.

Subsequently, liquid resin 16 is dropped from the dispenser 26 onto the insulating organic film 11. The liquid resin 16 is spread over the insulating organic film 11, and lower portions of the solder balls 10, the conductive pattern 17 and exposed area of the insulating organic film 11 are covered with the liquid resin 16 as shown in FIG. 7B. The liquid resin 16 rises around the solder balls 10 like a meniscus, and the dry flux 31 presents the conductive lands 13 from the liquid resin 16.

Subsequently, the resultant structure is placed in nitrogen atmosphere at 200 degrees to 250 degrees in centigrade. The liquid resin is thermally cured, and the resultant structure is covered with the reinforcing resin layer 16 except the upper portions of the solder balls 10. While the high-temperature nitrogen atmosphere is solidifying the liquid resin 16, the solder balls 10 are partially melted, and are strongly bonded to the conductive lands 13, respectively as shown in FIG. 7C. The reinforcing resin layer 16 enhances the stability of the solder balls 10 on the conductive lands 13. The reinforcing resin layer 16 does not allow the melted solder to flow out of the conductive lands 13, and any solder resist layer is required for the array of electrodes fabricated on the interposer 12. This results in reduction in production cost.

If the reinforcing resin reaches upper portions of the solder balls 10, the manufacturer chemically or mechanically removes the reinforcing resin from the upper portions of the solder balls 10. The array of electrodes and the fabrication process implementing the fourth embodiment achieve all the advantages of the first embodiment.

Fifth Embodiment

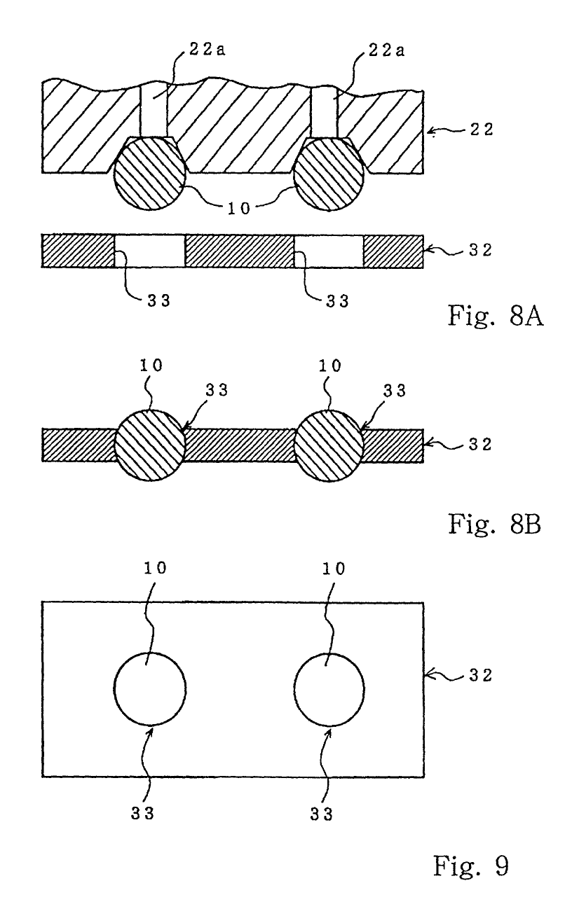

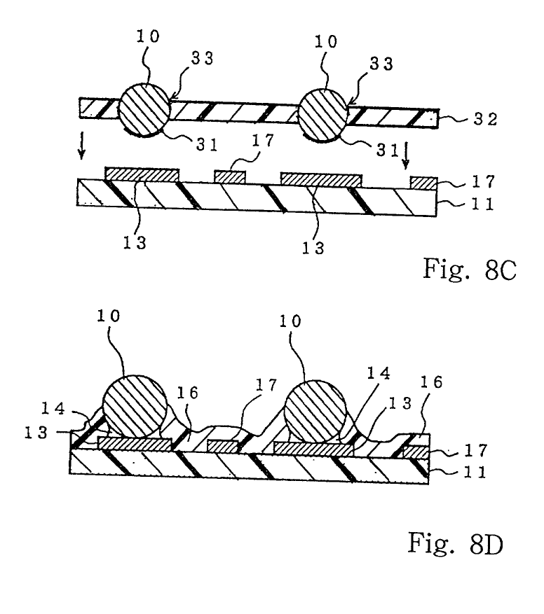

Still another array of electrodes embodying the present invention is fabricated on the interposer 12 through a process shown in FIGS. 8A to 8D. The process is similar to the process for the first embodiment until the step shown in FIG. 3E. FIGS. 8A to 8D illustrate the remaining steps of the process after the step shown in FIG. 3E.

A reinforcing resin sheet 32 is prepared. The reinforcing resin sheet 32 is thermally fusible and, thereafter, curable. Epoxy powder or other synthetic resin powder available for a molding is solidified. The reinforcing resin sheet 32 has the thickness equal to a third of the diameter of the solder balls 10. Through-holes 33 are formed in the reinforcing resin sheet 32, and are lain out on the pattern of the conductive lands 13. The diameter of the through-holes 33 is approximately equal to or slightly less than the diameter of the solder balls 10.

The solder balls 10 are clamped with the vacuum clamper 22, and are aligned with the through-holes 33, respectively as shown in FIG. 8A. The vacuum clamper 22 is downwardly moved, and releases the solder balls 10. The solder balls 10 are snugly received in the through-holes 33 as shown in FIG. 8B and FIG. 9.

Subsequently, the reinforcing resin sheet 32 is moved to the predetermined position over the insulating organic film 11, and lower portions of the solder balls 10 are coated with the flux 31. The flux 31 is of the type free from the cleaning. When the reinforcing resin sheet 32 reaches the predetermined position, the solder balls 10 are automatically aligned with the conductive lands 13, respectively. It is not necessary to align the individual solder balls 10 with the associated conductive lands 13. Thus, the alignment work is speedy. The reinforcing resin sheet 32 is downwardly moved as shown in FIG. 8C, and the solder balls 10 coated with the flux 31 are pressed against the conductive lands 13. The flux 31 is dried, and the solder balls 10 are fixed to the conductive lands 13 by using the conductive paste 14 such as the silver paste or the solder paste. The flux 31 may be replaced with flux to be learned thereafter.

When the solder balls 10 are fixed to the conductive lands 13, the reinforcing resin sheet 32 is slightly spaced from the insulating organic film 11. The reinforcing resin sheet 32 is heated to 100 degrees to 150 degrees in centigrade in nitrogen atmosphere or vacuum. Then, the reinforcing resin sheet is melted, and is spread over the insulating organic film 11. The solder balls 10 make the melted resin meniscus therearound, and upper portions of the solder balls 10 are uncovered with the melted resin 16. The flux 31 prevents the conductive lands 13 from the melted resin 16.

The melted resin is dried, and is solidified. As a result, the insulating organic film 11 is covered with the reinforcing resin layer 16 as shown in FIG. 8D. If the reinforcing resin is left on the upper portions of the solder balls 10, it is chemically or mechanically removed from the upper portions. The reinforcing resin layer 16 anchors the solder balls 10 to the insulating organic film 11, and enhances the stability of the solder balls 10 on the conductive lands 13. Any solder flows out of the conductive lands 13, and any solder resist is required. For this reason, the array of electrodes is fabricated on the interposer 12 at low cost.

As will be understood from the foregoing description, the reinforcing resin sheet 32 enhances the productivity by virtue of the concurrent alignment work for the solder balls 10. The conductive paste fixes the solder balls 10 to the conductive lands 13 without reflow, and any solder resist is required. Thus, the array of electrodes is fabricated on the interposer 12 at low cost.

Although particular embodiments of the present invention have been shown and described, it will be apparent to those skilled in the art that various changes and modifications may be made without departing from the spirit and scope of the present invention.

For example, the conductive paste may be spread on the solder balls 10. A process according to the present invention may not include the step of covering the upper portions of the solder balls 10 with the repellent agent. When the solder balls are large, the liquid resin does not reach the upper portions of the solder balls 10, and the manufacturer can eliminate the step from the process.

What is claimed is:

1. An array of electrodes fabricated on an insulating substrate having a conductive pattern on a major surface thereof, comprising:
plural electrodes fixed to said conductive pattern; and
an insulating resin layer directly covering a remaining portion of said major surface of said insulating substrate and said plural electrodes except surfaces of said plural electrodes so as to anchor said plural electrodes to said insulating substrate.

2. The array of electrodes as set forth in claim 1, in which said plural electrodes are fixed to said conductive pattern by means of conductive paste.

3. The array of electrodes as set forth in claim 2, in which said conductive paste is selected from the group consisting of silver paste, gold paste, copper paste and solder paste.

4. The array of electrodes as set forth in claim 1, said insulating resin layer has a meniscus configuration around each of said plural electrodes.

5. The array of electrodes as set forth in claim 4, in which said insulating resin layer is a thermosetting synthetic resin, and said meniscus configuration is formed during the thermosetting.

6. The array of electrodes as set forth in claim 5, in which said insulating resin layer is selected from the group consisting of polyimide resin, epoxy resin, phenol resin, acrylic resin and silicone resin.

7. The array of electrodes as set forth in claim 1, in which said electrodes are solder balls.

8. The array of electrodes as set forth in claim 7, in which said solder balls are formed on conductive lands of said conductive pattern forming a part of an interposer.

9. The array of electrodes as set forth in claim 8, in which said conductive pattern is fixed to electrodes of a semiconductor chip.

10. The array of electrodes as set forth in claim 1, in which said plural electrodes are formed of a heat-fusible conductive material, and are directly fixed to said conductive pattern by means of pieces of said heat-fusible conductive material fused therefrom.

11. The array of electrodes as set forth in claim 10, in which said heat-fusible conductive material is solder.

12. A process for fabricating an array of electrodes on an insulating substrate, comprising the steps of:
a) preparing electrodes and an insulating substrate including a conductive pattern formed on a major surface thereof and having conductive lands where said electrodes are to be fixed;
b) applying conductive paste on said electrodes or said conductive lands;
c) fixing said electrodes to said conductive lands by means of said conductive paste; and
d) covering said insulating substrate and predetermined surfaces of said electrodes with an insulating resin layer so as to anchor said electrodes to said insulating substrate.

13. The process as set forth in claim 12, in which said conductive paste is selected from the group consisting of silver paste, gold paste, copper paste and solder paste.

14. The process as set forth in claim 12, in which said step d) includes the sub-steps of
d-1) spreading a thermosetting liquid resin over the insulating substrate, and
d-2) applying said thermosetting liquid resin with heat so as to form said insulating resin layer from said thermosetting liquid resin.

15. The process as set forth in claim 14, in which said step d) further includes the sub-step of d-0) covering remaining surfaces of said electrodes with repellent layers before said step d-1), and said repellent layers are removed from said electrodes after said step d).

16. The process as set forth in claim 12, in which said electrodes are inserted into through-holes of an insulating resin film in such a manner that lower portions of said electrodes project from said insulating resin film in said step a).

17. The process as set forth in claim 16, in which said step d) includes the sub-steps of
d-1) melting said insulating resin film so as to cover said insulating substrate and said predetermined surfaces of said electrodes with liquid resin formed therefrom, and
d-2) solidifying said liquid resin so as to cover said insulating substrate and predetermined surfaces of said electrodes with said insulating layer.

18. The process as set forth in claim 16, in which said through-holes are laid on the pattern of said electrodes.

19. A process for fabricating an array of electrodes on an insulating substrate, comprising the steps of:
a) preparing electrodes and an insulating substrate including a conductive pattern formed on a major surface thereof and having conductive lands where said electrodes are to be fixed;
b) making said electrodes on said conductive lands dipped in thermosetting liquid resin spread over said insulating substrate; and
c) heating the resultant structure of said step b) so as to fix said electrodes to said conductive lands and solidify said thermosetting liquid resin for anchoring said electrodes to said insulating substrate.

20. The process as set forth in claim 19, in which said electrodes are formed of heat-fusible conductive material, and said step b) includes the sub-steps of
b-1) spreading said thermosetting liquid resin over said insulating substrate so as to cover said conductive pattern including said conductive island therewith,
b-2) bringing said electrodes into contact with said conductive lands, respectively, and
b-3) heating said thermosetting liquid resin and said electrodes of said heat-fusible conductive material with heat.

21. The process as set forth in claim 20, in which said step b) further includes the sub-step of b-4) putting said electrodes in positions on said conductive lands between said step b-2) and said step b-3).

22. The process as set forth in claim 21, in which said electrodes are put in said positions through applying supersonic vibrations.

23. The process as set forth in claim 19, further comprising the step of e) removing the solidified thermosetting resin from upper portions of said electrodes after said step d).

24. The process as set forth in claim 19, in which said electrodes are formed of heat-fusible conductive material, and said step b) includes the sub-steps of
b-1) placing said electrodes of said heat-fusible conductive material in positions on said conductive lands, respectively,
b-2) spreading said thermosetting resin over the resultant structure of said step b-1), and
b-3) heating said thermosetting liquid resin and said electrodes of said heat-fusible conductive material with heat.

25. The process as set forth in claim 24, in which said step b) further includes the step of b-4) applying flux to surfaces of said electrodes before said step b-1).
